(19) United States
(12) Patent Application Publication
(10) Pub. No.: US 2009/0109613 A1
(43) Pub. Date: Apr. 30, 2009

(54) MEMORY MODULE HEAT SINK

(75) Inventors: Anton Legen, Munich (DE); Steve Wood, Munich (DE)

Correspondence Address: MORRISON & FOERSTER LLP, 1650 TYSONS BOULEVARD, SUITE 400, MCLEAN, VA, 22102, US

(73) Assignee: QIMONDA AG

(21) Appl. No.: 11/653,403

(22) Filed: Jan. 16, 2007

(30) Foreign Application Priority Data
Jan. 17, 2006 (DE) 10 2006 002 090.1

(51) Int. Cl. H05K 7/20

(52) U.S. Cl. 361/679.54; 361/704; 361/709

(57) ABSTRACT

The invention relates to a memory module heat sink, in particular for FB-DIMM memory modules, for dissipating heat generated in the memory module to the outside, having an essentially planar metal plate (100, 150) to which the memory module can be fixed, wherein the metal plate (100, 150) has on its outer edge a stiffening element (110, 160) that runs at least partially along the outer edge.

The invention relates to a memory module heat sink, in particular for FB-DIMM memory modules, for dissipating heat generated in the memory module to the outside. The invention furthermore relates to a memory module having a corresponding memory module heat sink.

Fans are usually used for active cooling of electronic Components—such as a memory module for example—in a computer. Such fans are placed, for example, in a casing wall of the computer and serve to cool part of or the entire computer. In addition there is a need, in particular for powerful computers and computers having a very high memory requirements, such as for CAD applications or for file servers for example, to cool not only the processor and the power supply as usual, but also the memory modules.

At present memory modules in the form of, inter alia, SIMMs (Single Inline Memory Module), DIMMs (Dual Inline Memory Module) or RIMMs (RAM Bus Inline Memory Module) are used which differ with respect to the number of contacts and access times, but which are in principle of a similar design. A plurality of semiconductor memory chips are here placed on a circuit board designed as a plug-in card, which memory chips are connected via conductors and using switches to contacts at the edge of the circuit board. The semiconductor memory chips are arranged here on the circuit board in such a way that their longitudinal direction is perpendicular to the insertion direction of the memory module.

To install such a memory module in a computer, the circuit board or the plug-in card of the memory module is inserted with the side having the electrical contacts into a corresponding socket on a motherboard of the computer. The memory module should be designed to be sufficiently stiff for this purpose, as the memory module can be greatly bent if it is not handled properly, which leads to a high mechanical load on the memory module and on the contact terminals between the semiconductor memory chips and the memory module circuit board.

In order to meet the growing demand for memory, increasingly several of these memory modules are being inserted next to another onto the same motherboard. To increase performance, in addition to the semiconductor memory chips, said memory modules also have one or more logic ICs (Integrated Circuits) which are used to buffer clock signals and/or other input signals for example. The logic ICs are electrically connected to the memory module by means of solder globules and require more space on the memory module than the semiconductor memory chips. Owing to the size of the logic ICs, there is a risk that in particular their electrical contact terminals may be damaged by a bending or a torsion of the memory module circuit board.

In addition, owing to the processor speed, the memory modules are accessed at a very high frequency, which results in the memory module heating up greatly during continuous operation. In conjunction with the narrow spacing between the memory modules, firstly this leads to active cooling being required for the memory modules, and secondly said active cooling also functions effectively in the long term even when memory modules are spaced in close proximity to one another.

In order to effectively dissipate the heat of the memory module, the latter is surrounded by heat sinks. Such heat sinks for memory modules are composed of two metal plates arranged parallel to one another that cover all components of the memory module on its two large sides. The two metal plates are held in position by means of two mounting clips (steel springs) and hooks provided on the metal plates.

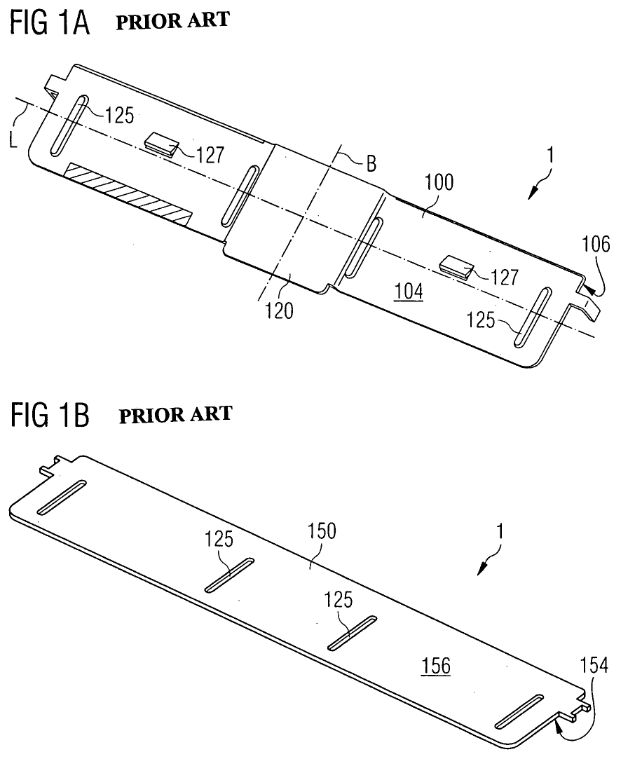

There is a reference design for such a heat sink from the firm Intel. Refer here also to FIGS. 1a and 1b and the associated descriptions of the prior art (see below). In addition, there are JEDEC standards relating to the maximum dimensions of such a heat sink, as well as to the position and form of fastening options on the memory module.

Differences in height, manufacturing-related tolerances and the surface characteristics of the memory module necessitate the use of a TIM (Thermal Interface Material) when using such a heat sink for cooling purposes. Such heat conducting media (also referred to as heat conducting pads or heat conducting pastes) preferably have an elastomer which should lie thinly and evenly between the memory module and the metal plate of the heat sink. The TIM materials require a certain pressure if they are to function properly. The pressure is preferably realized by means of the mounting clips, which press the two metal plates and the memory module perpendicularly onto one another.

The object of the invention is to provide an improved heat sink for memory modules, and an improved memory module having a heat sink. The heat sink should be designed here to be as mechanically stiff as possible and capable of effectively conducting away the heat generated in the memory module. Furthermore, the heat sink should require little space for the constricted conditions of memory modules mounted in close proximity to one another, so that sufficient cooling air can flow through between two directly adjacent memory modules.

This object is achieved by the independent claim 1. Advantageous refinements emerge from the respective dependent claims, wherein the features of claims 2 and 3 may however be provided per se themselves on a memory module heat sink or on a metal plate of a memory module heat sink respectively, and are preferably suitable for heat dissipation to cooling air flowing thereover.

According to the invention, an at least partially encircling stiffening element is provided on a metal plate of the memory module heat sink. The stiffening element is preferably situated at an outer edge of the metal plate, and at its ends covers a given angular area with respect to a center or to a center of gravity of the metal plate. This produces a stiffening of the heat sink and prevents a bending, buckling or twisting of a heat sink plate when subjected to load from a mounting clip. As a result, in turn a good thermal contact with the memory module is produced by means of the TIM material. The heat sink can consequently provide effective long-term cooling.

In a second variant of the invention—which however can also be provided per se itself on a metal plate of the memory module heat sink—a stiffening element designed as a scoop, a depression or as a projection is preferably situated in a central area of an outer side of a metal plate, wherein at least three sides of the preferably rectangular stiffening element are provided within a base area of the metal plate. That is to say, at most one side of the stiffening element is flush with an outer edge of the metal plate. The logic IC of the memory module can then be accommodated internally in the stiffening element between the stiffening element (scoop) of the metal plate and the memory module. The three sides of the stiffening element form here a U-shaped embossment on the metal plate, which produces a stiffening of the metal plate in the longitudinal and in the transverse direction. Furthermore, air can consequently flow along the metal plate next to the scoop and thus ensure a cooling of the memory module and realize an air exchange in a longitudinal direction over the metal plate. The space available between two directly adjacent metal plates within a computer can effectively be used for cooling, since the flow resistance for the cooling air is lower.

By virtue of these two variants, a stiff memory module is realized which is protected from damage, in particular from damage to the electrical terminals of the logic IC, for example during insertion into a computer. By virtue of the preferably stamped scoop, the height differences between the logic IC (e.g. a hub chip or AMB chip) and the rest of the memory module are equalized, with the result that the metal plate is less sensitive with respect to the manufacturing and assembly tolerances of all components.

In a third variant of the invention—which however can also be provided per se itself on a metal plate of the memory module heat sink—the metal plate has at least one cutout into which a projection of the mounting clip of the memory module heat sink corresponding to the cutout can engage. By virtue of the provision of such a detent of the mounting clip on the metal plate, other detents for the mounting clip are unnecessary, so that the flow of cooling air over the metal plate is not additionally disturbed.

In one preferred embodiment of the invention, the encircling stiffening element on the outer edge of the metal plate projects out on the side of the metal plate which is arranged opposite a memory module. This allows short-circuits on the memory module to be avoided.

In one preferred embodiment of the invention, a stiffening element is provided on at least one of the two longitudinal edges over all sections in the longitudinal direction of the metal plate. A stiffening element is preferably provided here on at least one longitudinal side, over its entire longitudinal extent. As a consequence, in comparison with a conventional strip-shaped rectangular cross-section, the area moments of inertia are increased for all cross-sections of the metal plate in the longitudinal direction, with the result that a stiff design of the metal plate is produced in longitudinal and transverse direction over its entire longitudinal extent.

In one preferred embodiment of the invention, a stiffening element runs in a U-shape on the outer edge of the metal plate. As a consequence, a stiff design is additionally achieved in the transverse direction of the metal plate.

In one preferred embodiment of the invention, the stiffening element is provided completely or virtually completely encircling the outer edge of the metal plate.

In one preferred embodiment of the invention, all four sides of a square or rectangular scoop are situated within the base area of a metal plate. This produces an extra-stiff design of the metal plate in both the longitudinal and transverse directions.

In one preferred embodiment of the invention, the memory module heat sink is composed of two essentially planar and mutually parallel metal plates, which are provided accordingly with stiffening elements and between which the memory module is arranged.

The invention further relates to a mounting clip for a memory module heat sink according to the invention which clamps at least one metal plate to a memory module. In this arrangement, the mounting clip has on its free end sections a projection whose form corresponds to a cutout in the respective metal plate of the memory module heat sink. The projection preferably has a circular cross-section here.

The invention will be explained in greater detail below in relation to exemplary embodiments with reference to the attached drawing, in which:

FIG. 1a shows a three-dimensional representation of a cover plate of a memory module heat sink according to the prior art;

FIG. 1b shows a three-dimensional representation of a baseplate corresponding to the cover plate of FIG. 1;

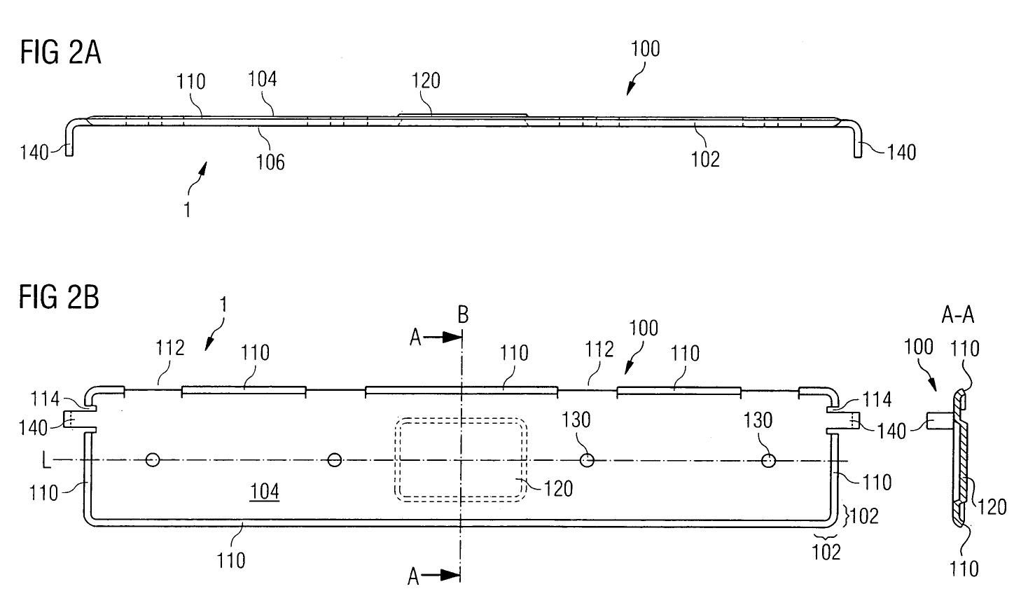

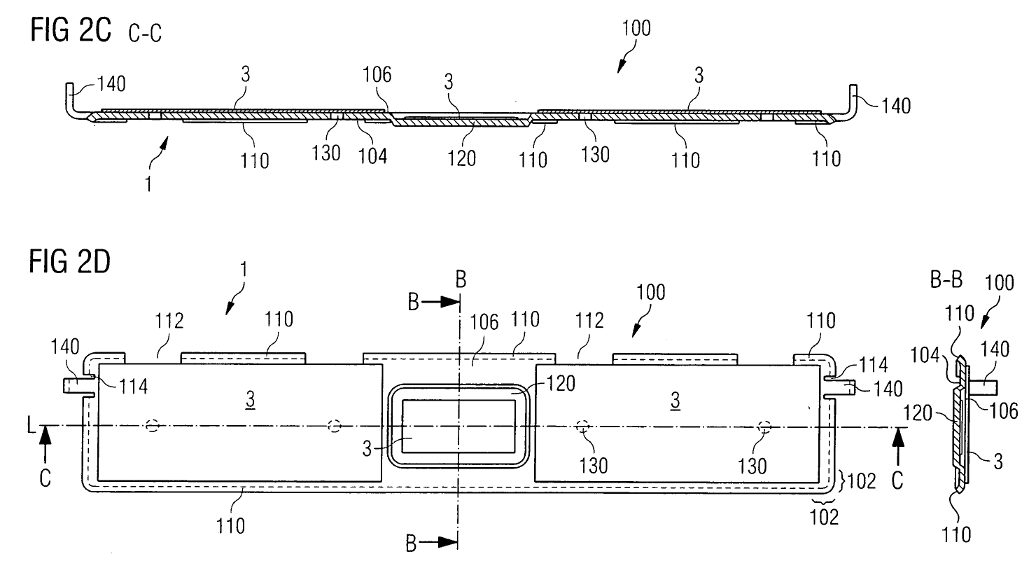

FIG. 2a shows a longitudinal side view of a cover plate according to the invention of a memory module heat sink according to the invention without TIM material applied thereto;

FIG. 2b shows a plan view of the cover plate of FIG. 2a and a sectional side view along a plane A-A;

FIG. 2c shows a longitudinal, centrally sectional side view, rotated by 180° in relation to FIG. 2a, of the cover plate according to the invention with TIM material applied thereto;

FIG. 2d shows a bottom view of the cover plate from FIG. 2c and a sectional side view along a plane B-B;

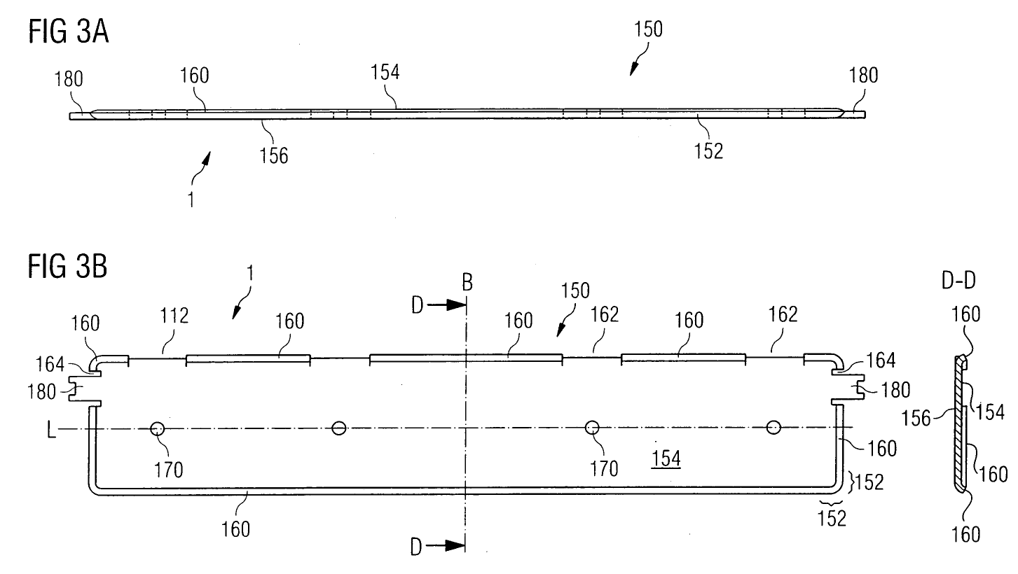

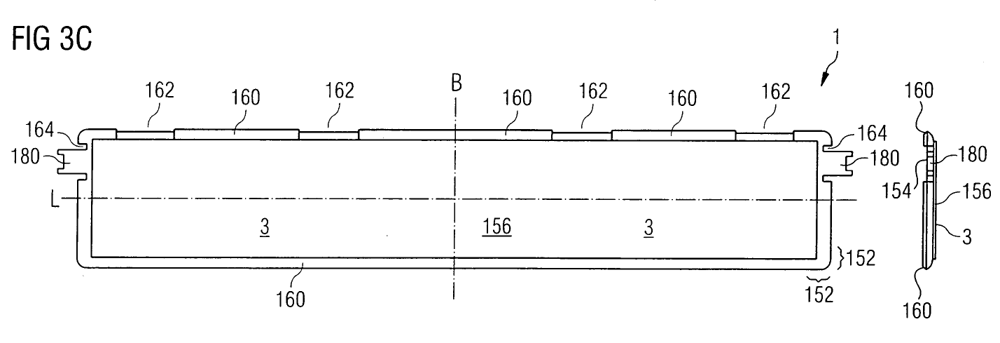

FIG. 3a shows a longitudinal side view of a baseplate according to the invention of the memory module according to the invention without TIM material applied thereto;

FIG. 3b shows a plan view of the baseplate of FIG. 3a and a sectional side view along a plane D-D;

FIG. 3c shows a bottom and a side view of the baseplate according to the invention with TIM material applied thereto;

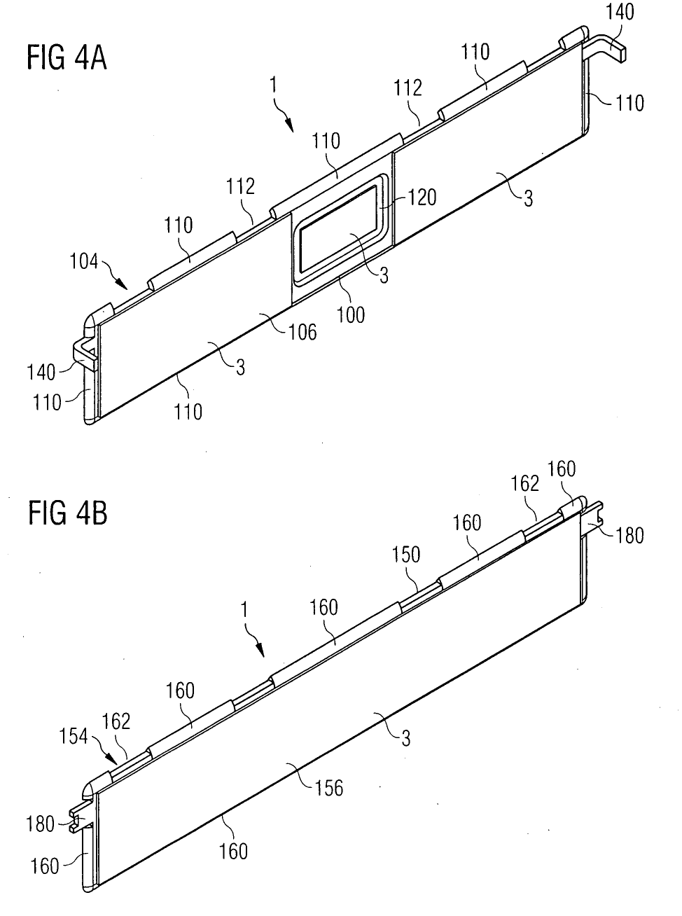

FIG. 4a shows a three-dimensional representation of the cover plate according to the invention with TIM material applied thereto;

FIG. 4b shows a three-dimensional representation of the baseplate according to the invention with TIM material applied thereto;

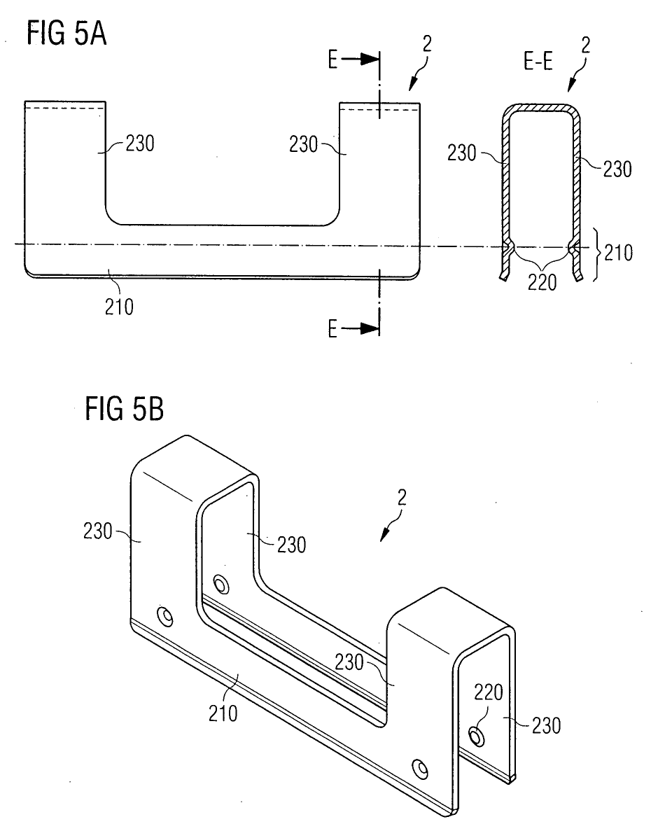

FIG. 5a shows a longitudinal side view and a sectional side view along the plane E-E of a mounting clip according to the invention for the memory module heat sink according to the invention;

FIG. 5b shows a three-dimensional representation of the mounting clip from FIG. 5a from diagonally above; and

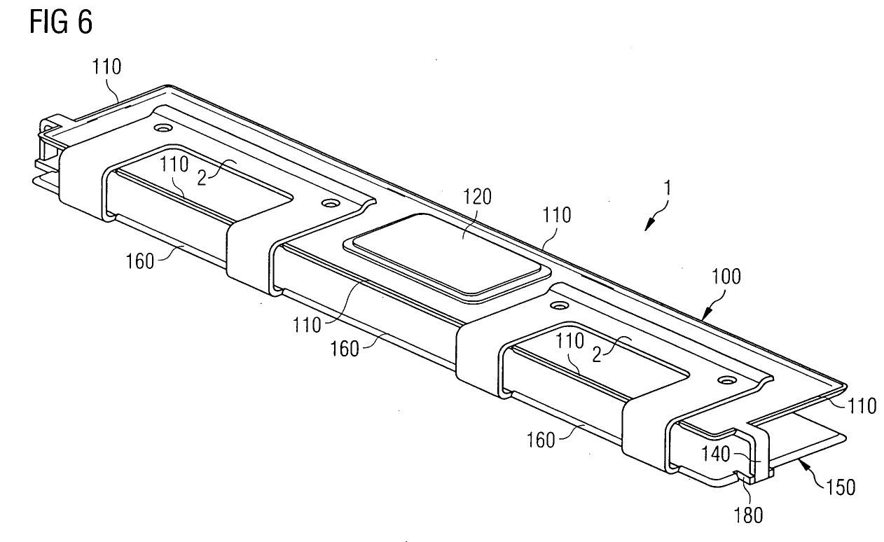

FIG. 6 shows a three-dimensional representation of a mounted memory module heat sink without a memory module interposed.

The invention will be explained below starting from the prior art represented in FIGS. 1a and 1b.

A memory module heat sink 1 according to the prior art has a cover plate 100 (FIG. 1a) and a baseplate 150 (FIG. 1b). The cover plate 100 has a scoop 120 in the center which extends over the entire width B of the cover plate 100. That is to say, every cross-section in the longitudinal direction L through the entire cover plate 100 has a U-shaped section or area with short flanks. The scoop 120 is essentially rectangular, with two mutually parallel sides running over the cover plate 100 in the lateral direction B. Said two sides are likewise parallel to the longitudinal ends of the cover plate 100. One side of the scoop 120 which is perpendicular thereto closes off the cover plate 100 with an outer edge, the side lying opposite thereto projecting slightly from the side edge of the cover plate 100.

The cover plate 100 and the baseplate 150 furthermore have beads 125 extending over the respective plate 100, 150 in the lateral direction B, which beads are stamped out of or embossed on the material of the respective plates 100, 150. The beads 125 extend in the lateral direction B within the respective plate 100, 150 over approximately ⅔ of the width B and serve for the guidance of a mounting clip, not shown in FIGS. 1a and 1b, which clamps a memory module between the cover plate 100 and the baseplate 150. In this arrangement, lateral clip ends slide along the beads 125, which guide the mounting clip when it is pushed on. When the mounting clip is pushed on, it slides over an embossment 127, having an oblique flank, of the cover plate 100 which prevents the mounting clip in its mounting position sliding off the cover plate 100 again.

In the remaining areas, the cover plate 100 and the baseplate 150 extend in one plane in each case. The cover plate 100 and the baseplate 150 are composed of, for example, a stamped metal sheet. On the one hand the sheet should be stiff, so that the respective plate 100, 150 does not bend or twist. On the other hand the respective plate 100, 150 should be thin so that it requires the minimum amount of space on the memory module or within the computer.

According to the invention, a cover plate 100 according to the invention will be presented with reference to FIGS. 2a to 2d, and a baseplate 150 according to the invention of a memory module heat sink 1 according to the invention will be presented with reference to FIGS. 3a to 3c (cf. also FIG. 6). According to the invention, the cover plate 100 and the baseplate 150 have a stiffening element 110, 160 on their respective outer edges 102, 152.

The following statements for a stiffening element 110, 160 of a metal plate 100, 150 are also applicable to the respective other metal plate 150, 100. In relation to an inner side 106 of the cover plate 100, the stiffening element(s) 110 is/are preferably arranged symmetrically in relation to the stiffening element(s) 160 of the baseplate 150, in turn with respect to their inner side 156.

The cover plate 100 according to the invention of the memory module heat sink 1 according to the invention will first be explained in greater detail with reference to FIGS. 2a, 2b, 2d and 4a.

The cover plate 100 is essentially a flat cuboid extending in one plane which is preferably deep drawn or stamped out of a metal sheet. The cover plate 100 having an essentially rectangular base area (seen best in FIGS. 2b and 2d) has a stiffening element 110 on its outer edge 102. The stiffening element 110 can be provided here with interruptions in some places on the outer edge 102. The stiffening element 110 here encircles the periphery of the cover plate 100 to some extent.

In one preferred embodiment of the invention, the stiffening element 110 completely encircles the cover plate 100. In the exemplary embodiment illustrated, however, the stiffening element 110 has recesses 112 for a mounting clip 2 (see FIGS. 5a, 5b and 6) as well as recesses 114 for a fastening 140 of the cover plate 100 on the baseplate 150. The stiffening element 110 is preferably provided over at least one longitudinal side along the cover plate 100. Alternatively, however, it is also possible for the stiffening elements 110 to be provided on alternate sides on the longitudinal sides, as long as at least one such stiffening element is provided on one of the two longitudinal sides at each position in the longitudinal direction of the cover plate. This is optional however. Stiffening elements 100 should be provided in particular where the cover plate 100 has a tendency to bend as a result of the clamping force of the mounting clip 2. The stiffening element 100 can be omitted at points subjected to little or no load.

The stiffening element 110 is provided on the cover plate 100 in such a way that when the cover plate 100 is subsequently mounted on a memory module, no damage, nor any short-circuiting during operation of the memory module, is caused by the mounting clip 2. For this purpose, on the one hand the stiffening element 110 is provided on the outer edge 102 of the cover plate 100 and pointing away from the memory module to be subsequently arranged on the cover plate 100. Other positions of this stiffening element 110 which extends principally in the longitudinal direction L of the cover plate 100 are possible, as long as they subsequently have no effect on the functioning of the heat sink or of the memory module. For instance it is possible to provide the stiffening element 110 not on the outer edge 102, but rather within the base area of the cover plate 100. With this arrangement, the stiffening elements 110 must not run in the longitudinal direction L or lateral direction B, but rather, for example, transversely thereto, and their form is optional. What is important, however, is that the stiffening element 110 has a component in the longitudinal direction L of the cover plate 100.

In one preferred embodiment of the invention, the stiffening element 110 is recessed only at the points at which the mounting clip 2 requires access to the outer side 104 of the cover plate 100. This applies however only to the flanks 230 of the mounting clip 2 that run beyond the edge of the cover plate 100.

In one preferred embodiment of the invention, the stiffening elements 110 may be bent not only toward the outer side 104, but also toward the inner side 106. The stiffening elements 110 are preferably designed as ribs 110. The ribs 110 are here preferably bent up from the material of the cover plate 100 at the lateral edges 102. The ribs 110 have an essentially rectangular form here. Other forms of the ribs 110, such as square, trapezoidal, triangular, with or without rounded edge, are of course possible.

The cover plate 100 further has a scoop 120 which projects from the cover plate 100 in one area thereof. The scoop 120 is here integrally connected with the material of the cover plate 100. This also applies to the stiffening elements 110, which are likewise preferably integrally formed with the cover plate 100. It is however also possible to provide both the scoop 120 and the stiffening elements 110 as a separate part on the cover plate 100, and to push these, for example, into a guide in the cover plate 100, with the stiffening elements 110 and/or the scoop 120 being held by means of undercuts.

The scoop 120 is preferably situated in a central middle region of the cover plate 100, with all four sides of the scoop 120 preferably being arranged within the base area of the cover plate 100. It is however also possible to provide the scoop 120 with its sides lying parallel to the longitudinal side of the cover plate 100 up to the outer edge 102 of the cover plate 100. This can also be done with just one longitudinal side of the scoop 120.

The base area of the scoop 120 is not limited to a rectangular form, but rather may be, for example, partially circular, or have sides directly adjacent to one another which are not mutually perpendicular. In the state with the cover plate 100 mounted on the memory module, an upper side of a logic IC lies against the inner side 106 of the scoop 120, if appropriate with a TIM material 3 (Thermal Interface Material) in between. Furthermore, the inner side 106 of the cover plate 100 likewise lies against an outer side of the memory module. A TIM material 3, which is shown only in FIGS. 2c, 2d and 4a, is likewise preferably situated here between the inner side 106 of the cover plate 100 and the outer side of the memory module.

In addition, the cover plate 100 has cutouts 130 which serve as detents for the mounting clip 2 on the cover plate 100. Such cutouts 130 are preferably provided here for each mounting clip 2. It is however also possible for a different number of cutouts 130, such as a single cutout, or three or more cutouts, to be provided for each mounting clip 2. The cutouts 130 preferably lie on a central longitudinal axis L of the cover plate 100, as this ensures that a clamping force is exerted from the mounting clip 2 centrally into the cover plate 100, and from there centrally into the memory module. The cutouts 130 are preferably blind holes or through-holes. Embossed or stamped cutouts 130 are of course likewise possible. The cutout 130 has here a form corresponding to a projection 220 of the mounting clip 2. That is to say, in a mounted state the projection 220 of the mounting clip 2 engages positively into the cutout 130.

The cover plate 100 furthermore has a fastening 140 in each case at its two longitudinal ends (i.e. transverse sides). Said fastening 140 is preferably designed as a lug 140 that can engage in a fastening 180 of the baseplate 150. The fastening 180 of the baseplate 150 is designed here as a hook or U-hook. Other fastenings between the cover plate 100 and baseplate 150, which preferably operate according to the key/lock principle, may of course likewise be used.

In the same or analogous way as the cover plate 100, the baseplate 150 (see FIGS. 3a, 3b, 3c and 4b) is designed with a stiffening element 160. The stiffening element 160 of the baseplate 150 likewise preferably extends on the outer edge 152 of the baseplate 150 and is bent toward its outer side 154, that is to say away from its inner side 156. The stiffening element 160 may however also be bent toward the inner side 156.

Given a combination of cover plate 100 and baseplate 150 (memory module heat sink 1), both stiffening elements 110, 160 need not necessarily point away from the respective outer side 104, 154 of the plates 100, 150, but rather one stiffening element 110, 160 may point inward, while the other stiffening element 160, 110 points outward. The converse is also possible. The stiffening element 160 of the baseplate 150 is likewise preferably designed as a rib 160, which may likewise take the forms of the rib 110 of the cover plate 100. Furthermore, the baseplate 150 likewise has cutouts 170 for the projections 220 of the mounting clip 2. An arrangement and number of the cutouts 170 is here preferably analogous to the cover plate 100.

However, the baseplate 150 preferably does not have a scoop 120. As a result, as shown in FIGS. 3c and 4b, the TIM material 3 can be provided over the entire longitudinal and lateral extent of the baseplate 150.

FIGS. 5a and 5b show a mounting clip 2 according to the invention which is designed in a U-shape in each case in a side and a front view, which can be readily seen in FIG. 5a. The mounting clip 2 is here bent out of a spring plate or spring steel, and has two free end sections 210 on which is formed in each case at least one projection 220 which engages with the corresponding cutout 130, 170 of the cover plate 100 or baseplate 150 respectively. The respective free end section 210 is formed on two flanks 230 of the mounting clip 2 lying in one plane, wherein the two free end sections 210 lie directly opposite one another with respect to a central symmetrical plane of the mounting clip 2.

The mounting clip 2 has furthermore essentially the form of an elongated U-shaped bracket with the center removed, with said cutout having the form of a cuboid. The free ends of the free end sections 210 are furthermore bent slightly outward from the plane of the respective flank 230 out of the mounting clip 2 to facilitate pushing the mounting clip 2 onto the memory module heat sink 1 according to the invention.

The projections 220 provided at the free end sections 210 preferably have a circular base area and are preferably designed as nubs 220. The nub 220 can here—as can be seen in the sectional view FIG. 5a—be embossed or stamped from the outer side of the mounting clip 2 inward into the mounting clip 2. The projections 220 protruding inwardly into the mounting clip 2 are preferably provided at the same height as the free end section 210. This may also differ in one embodiment of the invention wherein, for example, the projection(s) 220 of a free end section 210 are provided on a different height from the projection(s) of the free end sections 210 lying opposite. The same applies analogously to the cover plate 100 and the baseplate 150, the respective cutouts 130, 170 of which are then no longer in line with, for example, a central longitudinal axis L of the memory module heat sink 1 according to the invention.

FIG. 6 shows the memory module heat sink 1 according to the invention in its mounted state, but without a memory module to be cooled arranged between the cover plate 100 and the baseplate 150. The cover plate 100 and the baseplate 150 are fixed here in two spatial directions via the fastening 140 designed as a lug 140 of the cover plate 100 and the fastening 180 designed as a hook 180 of the baseplate 150. A fixing in the third spatial direction is achieved firstly via the memory module and secondly via the mounting clip 2 pushed over the cover plate 100 and the baseplate 150.

According to the invention, two mounting clips 2 are provided, wherein the projections 220 of the mounting clips 2 engage in the respective cutout 130, 170 of the cover plate 100 or baseplate 150 respectively. As a result, a stiff and firmly clamped memory module having a memory module heat sink 1 is realized.

### LIST OF REFERENCE SYMBOLS

1 Memory module heat sink, heat sink

100 Cover plate, plate, metal plate

102 Outer edge of cover plate 100

104 Outer side of cover plate 100, side

106 Inner side of cover plate 100, side

110 Stiffening element, rib

112 Recess for clip 2

114 Recess for fastening 140

120 Stiffening element, scoop

125 Bead (prior art only)

127 Embossment (prior art only)

130 Cutout, bore, through-hole

140 Fastening, lug

150 Baseplate, plate, metal plate

152 Outer edge of baseplate 150

154 Outer side of baseplate 150, side

156 Inner side of baseplate 150, side

160 Stiffening element, rib

162 Recess for clip 2

164 Recess for fastening 180

170 Cutout, bore, through-hole

180 Fastening, hook, U-hook

2 Fastening, mounting clip

210 Free end section

220 Projection, nub

230 Flank

3 TIM (Thermal Interface Material), elastomer, heat conducting paste

L Length, longitudinal direction of cover plate 100 and baseplate 150

B Width, lateral direction of cover plate 100 and baseplate 150

1. A memory module heat sink, in particular for FB-DIMM memory modules, for dissipating heat generated in the memory module to the outside, having
an essentially planar metal plate to which the memory module can be fixed, wherein the metal plate has on its outer edge a stiffening element that runs at least partially along the outer edge.

2. The memory module heat sink as claimed in claim 1, wherein the metal plate has a, preferably central, stiffening element that projects from its outer side, wherein
the stiffening element is designed as a scoop in which an electronic chip of the memory module can be partially accommodated, and
at least three sides of the scoop (120) are provided within a base area of the metal plate.

3. The memory module heat sink as claimed in claim 1, wherein the metal plate has in its side a cutout with which a projection of a mounting clip corresponding to the cutout can engage, by means of which mounting clip the metal plate can be fixed to the memory module.

4. The memory module heat sink as claimed in claim 1, wherein the stiffening element of the metal plate preferably points away from the memory module with respect to the memory module that can be fixed to the metal plate, and/or the stiffening element points toward the memory module.

5. The memory module heat sink as claimed in claim 1, wherein a stiffening element is provided on the longitudinal section of the outer edge that lies, with respect to a longitudinal axis of the metal plate, directly opposite a longitudinal section of the outer edge on which the stiffening element is recessed.

6. The memory module heat sink as claimed in claim 1, wherein a stiffening element extends over a complete longitudinal side of the metal plate.

7. The memory module heat sink as claimed in claim 1, wherein a stiffening element of the metal plate runs in a U-shape on the outer edge of the metal plate.

8. The memory module heat sink as claimed in claim 1, wherein the stiffening element encircles the metal plate virtually completely on the outer edge of the metal plate, and
is recessed for mounting clips only on a single longitudinal side, and for a fastening with a second metal plate on the two transverse sides.

9. The memory module heat sink as claimed in claim 1, wherein two essentially planar and mutually parallel metal plates, a cover plate and a baseplate are provided, between which the memory module can be clamped, preferably with the aid of at least one mounting clip.

10. The memory module heat sink as claimed in claim 1, wherein the scoop (120) protrudes from an inner side (106) and the outer side (104) of the cover plate (100).

11. The memory module heat sink as claimed in claim 1, wherein all four sides of the scoop are provided within the base area of the cover plate.

12. The memory module heat sink as claimed in claim 1, wherein the scoop projects further from a surface of the cover plate than the stiffening element.

13. The memory module heat sink as claimed in claim 1, wherein the scoop is stamped into or embossed on the cover plate.

14. The memory module heat sink as claimed in claim 1, wherein the cutouts in the metal plates are blind holes or embossments or through-holes.

15. The memory module heat sink as claimed in claim 1, wherein two cutouts are provided in each metal plate for a single mounting clip.

16. The memory module heat sink as claimed in claim 1, wherein the cutouts of a single metal plate lie on a straight line running preferably centrally in the longitudinal direction with respect to the metal plate.

17. The memory module heat sink as claimed in claim 1, wherein the metal plates are deep drawn.

18. A memory module having a heat sink as claimed in claim 1.

19. The memory module as claimed in claim 18, wherein the memory module is connected firmly to the heat sink by means of a mounting clip.

20. The memory module as claimed in claim 18, wherein a good thermally conductive material, preferably a good thermally conductive elastomer or a TIM material, is arranged between a metal plate and the memory module.

21. A memory module heat sink mounting clip for fastening a memory module heat sink as claimed in claim 1 on a memory module, wherein
the mounting clip has on at least one free end section a projection pointing inward into the mounting clip.

22. The memory module heat sink mounting clip as claimed in claim 21, wherein the projection of the mounting clip has a circular base area.

23. The memory module heat sink mounting clip as claimed in claim 21, wherein the projection of the mounting clip is a nub or an embossment.
